(19) United States
(12) Patent Application Publication
(10) Pub. No.: US 2026/0214798 A1
(43) Pub. Date: Jul. 23, 2026

(54) CIRCUIT BOARD AND SEMICONDUCTOR PACKAGE

(71) Applicant: LG INNOTEK CO., LTD., Seoul (KR)

(72) Inventor: Tae Gyu KANG, Seoul (KR)

(73) Assignee: LG INNOTEK CO., LTD., Seoul (KR)

(21) Appl. No.: 19/456,330

(22) Filed: Jan. 22, 2026

(30) Foreign Application Priority Data
Jan. 23, 2025 (KR) 10-2025-0010601

(51) Int. Cl. H05K 1/11; H05K 1/181

(52) U.S. Cl. CPC H05K 1/113; H05K 1/181; H05K 2201/0302; H05K 2201/09472

(57) ABSTRACT

This embodiment relates to a circuit board and a semiconductor package. The circuit board according to one aspect comprises: an insulating layer; and a via electrode penetrating at least a portion of the insulating layer, wherein the via electrode includes a first layer, a second layer disposed on the first layer, and a third layer disposed between the first layer and the second layer and having a thickness thinner than the thickness of the first layer and the second layer, and wherein the grain size of the third layer is smaller than the grain size of the second layer.

### TECHNICAL FIELDS

The teachings in accordance with exemplary and non-limiting embodiments of the present invention relate generally to a circuit board and a semiconductor package, and more particularly to a circuit board and semiconductor package.

### BACKGROUND ARTS

Recent trends in electronic technologies such as AI and servers are moving towards multi-functionality and high-speed operation. To respond to these trends, circuit board technologies for high-layer count and large-area production are also advancing rapidly, keeping pace with the fast-developing semiconductor chip manufacturing technology.

Particularly, as the density of transistors and wiring within semiconductor chips increases, the number of I/O terminals on these chips is rising. To address this trend, circuit boards are not only seeing finer wiring density, length, and width, but also progressing towards high-layer count and large-area designs.

Furthermore, from the perspective of miniaturizing finished electronic products, the thickness of the circuit boards employed is also decreasing. Technologies related to multilayer circuit boards, which incorporate more circuit layers within boards of the same thickness, are being actively researched. Additionally, as semiconductor chip pitches become narrower and chip sizes increase, research is underway into chiplet technology, which separates semiconductor chips by function. Furthermore, technologies for connecting these separated chiplets on the circuit board are being actively researched. Moreover, by connecting semiconductor chips with different functions on the circuit board, technologies concerning the interconnection relationship between the circuit board and semiconductor chips - such as the circuit board connecting semiconductor chips - are being actively researched. This represents a shift from the traditional perspective of considering the circuit board solely from the standpoint of semiconductor packaging.

A circuit board refers to an insulating substrate with conductive material such as copper disposed in circuit line patterns, collectively designating the package substrate (board) immediately prior to mounting electronic components. To densely mount numerous types of electronic components on a flat plate, the mounting positions for each component are determined, and the circuit patterns connecting the components are printed onto the plate surface and fixed.

A circuit board comprises multiple insulating layers disposed vertically, wiring layers disposed on each insulating layer, and via electrodes penetrating the multiple insulating layers. Pads are disposed on the surface of the circuit board, and these pads can be electrically connected to electronic components such as semiconductor chips. In line with the recent trend towards higher integration in semiconductor packages, the number of terminals on electronic devices is also increasing, leading to more complex wiring. Consequently, the implementation of fine-pitch pads disposed on the circuit board is a critical factor that must be considered for the quality of the circuit board.

The implementation of pads on a circuit board is achieved through a plating method utilizing a seed layer disposed on the surface of the insulating layer. Following plating to form the pads, the seed layer is subsequently removed by etching. As the thickness of the seed layer increases, etching efficiency decreases, and consequently, the thickness of the seed layer is trending towards being thinner to enable the realization of fine-pitch pads.

Furthermore, during the pad formation process, a via electrode penetrating the insulating layer may also be formed concurrently. In this case, the seed layer is disposed on the surface of the lower wiring portion connected vertically to the pad, the inner wall of the via hole within the insulating layer, and the surface of the insulating layer where the pad is formed.

According to the aforementioned method, differences in thickness across regions within the seed layer can lead to issues such as voids forming within the via electrode, resulting in poor plating quality.

### PRIOR TECHNICAL DOCUMENT

### Patent Document

Korea Public Patent Gazette No.: 10-2009-0087154 (Published on 17, Aug. 2009)

### SUMMARY OF THE INVENTION

### Technical Subject

The present invention is to provide an improved printed circuit board and semiconductor package that facilitates the realization of fine pitch while enhancing the plating quality of via electrodes.

### Technical Solution

A circuit board according to one aspect of the present invention may comprise: an insulating layer; and a via electrode penetrating at least a portion of the insulating layer, wherein the via electrode includes a first layer, a second layer disposed on the first layer, and a third layer disposed between the first layer and the second layer and having a thickness thinner than the thickness of the first layer and the second layer, and wherein the grain size of the third layer is smaller than the grain size of the second layer.

A semiconductor package according to another aspect of the present invention may comprise: an insulating layer; a semiconductor chip disposed on the insulating layer; and a via electrode penetrating at least a portion of said insulating layer, wherein the via electrode may include: a first layer, a second layer disposed on the first layer, and a third layer disposed between the first layer and the second layer and having a thickness thinner than the thickness of the first layer and the second layer, wherein the grain size of the third layer is smaller than the grain size of the second layer.

### ADVANTAGEOUS EFFECTS

According to the present embodiments, it is possible to minimize the lifting phenomenon of the pad portion due to thickness variations across different regions of the seed layer, as well as the degradation of plating quality within the via electrode.

Furthermore, for the pad portion that is plated together with the via electrode, the thickness of the seed layer formed for creating the pad portion can be made thinner, thus offering the advantage of facilitating the realization of fine patterns.

### BRIEF DESCRIPTIONS OF DRAWINGS

FIG. 1 is a cross-sectional view of a circuit board according to an embodiment of the present invention.

FIG. 2 is an enlarged view of the via electrode shown in FIG. 1.

FIGS. 3 to 6 are views illustrating the formation process of the via electrode and pad portion according to an embodiment of the present invention.

FIG. 7 is a cross-sectional view of a semiconductor package according to an embodiment of the present invention.

### BEST MODES

Hereinafter, the attached drawings are referred to in detail to explain the preferred embodiment of the present invention.

However, the technical idea of the present invention is not limited to the some embodiments described, but can be implemented in various different forms, and within the scope of the technical idea of the present invention, one or more of the components between the embodiments can be selectively combined or replaced.

In addition, the terms used in the embodiments of the present invention (including technical and scientific terms) can be interpreted to mean what a person with ordinary skill in the art would understand, unless explicitly defined and described, and generally understood by a person with ordinary skill in the art. Generally used terms, such as those defined in dictionaries, can be interpreted in the context of the relevant technology.

Furthermore, the terms used in the embodiments of the present invention are intended to explain the embodiments and are not intended to limit the invention. In this specification, the singular form may include the plural form unless otherwise specified in the text, and when described as ‘A and (and/and) B, C, at least one (or more than one) of A, B, and C,’ it may include one or more of all combinations of A, B, and C.

In addition, terms such as 1, 2, A, B, (a), and (b) may be used to describe the components of the embodiments of the present invention. Such terms are intended only to distinguish the component from other components and are not limited by the nature, order, or sequence of the component.

And, if any component is described as being ‘connected’, ‘coupled’ or ‘attached’ to another component, that component may be directly connected, coupled or attached to that other component, as well as being ‘connected’, ‘coupled’ or ‘attached’ to another component that is between that component and that other component.

In addition, when it is stated that each component is formed or arranged ‘above or below’, the above or below includes not only the case where two components are directly in contact with each other, but also the case where one or more other components are formed or arranged between the two components. In addition, when it is expressed as ‘upper or lower’, it can include the meaning of the lower direction as well as the upper direction based on one component.

Furthermore, the expression that configuration A is disposed between configurations B and C must also encompass the meaning that configuration A is disposed such that at least part of it overlaps with configurations B and C in the horizontal and/or vertical directions.

Expressions referring to direction include horizontal direction and vertical direction, and the horizontal direction includes a first horizontal direction and a second horizontal direction perpendicular to the first horizontal direction. This corresponds to the Cartesian coordinate system, where the first horizontal direction is the X-axis, the second horizontal direction is the Y-axis, and the vertical direction is the Z-axis. The meaning of overlapping along a horizontal direction must also include overlapping along the first horizontal direction and/or overlapping along the second horizontal direction.

Furthermore, the meaning that component A is exposed from component B should be understood as meaning that it is exposed from component B, not that it is exposed from the product claimed by component A. That is, when it is stated that component A is exposed from component B, it should be understood to mean that component A is not exposed from the product claimed by component C, which is other than component B.

Furthermore, where it is stated that component A “contacts” component B, this may encompass not only direct “contact” between the components themselves, but also “contact” mediated by another component situated between them. Therefore, where it is intended that component A should only be understood as being in “direct contact” with component B, it shall be stated as being in “direct contact”.

Furthermore, where it is stated that Configuration A is “covered” by Configuration B, this should be understood to mean that Configuration A is covered by Configuration B, such that at least some part of Configuration A is covered by Configuration B, taking into account the functionality and purpose being addressed. Unless specifically stated otherwise, it should not be understood that Configuration A is entirely covered by Configuration B.

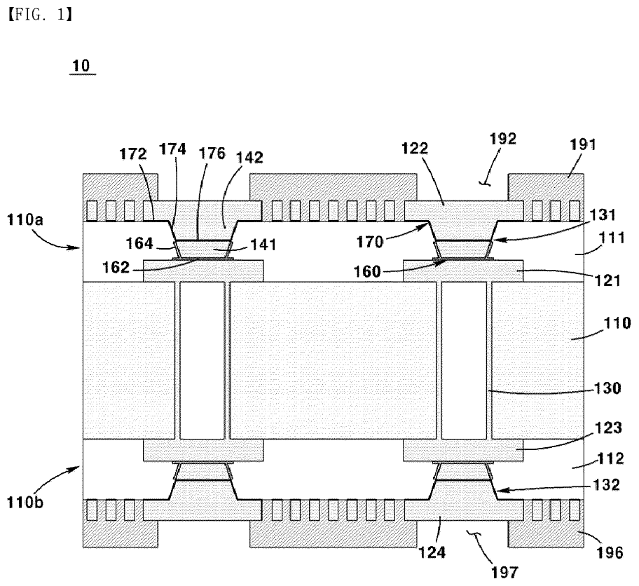

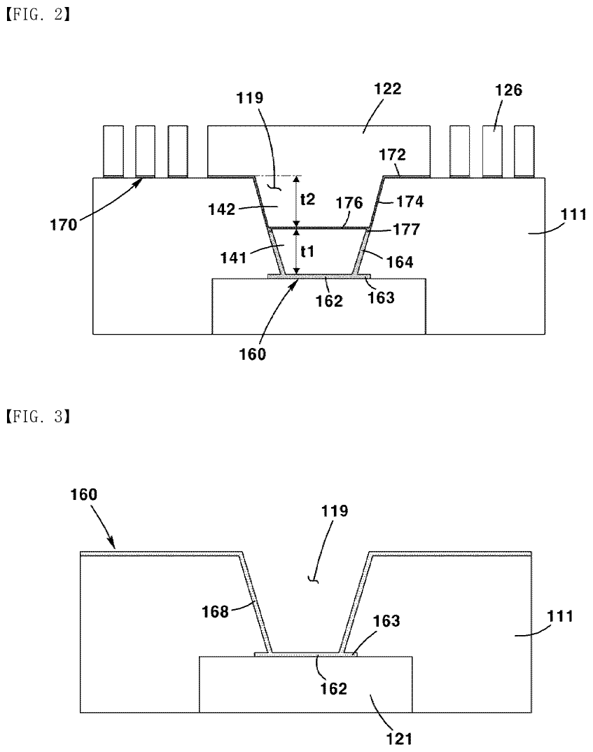

FIG. 1 is a cross-sectional view of a circuit board according to an embodiment of the present invention, FIG. 2 is an enlarged view of the via electrode shown in FIG. 1, and FIGS. 3 to 6 are views illustrating the formation process of the via electrode and pad portion according to an embodiment of the present invention.

Referring to FIGS. 1 to 6, a circuit board (10) according to an embodiment of the present invention may comprise a core layer (110), a first build-up structure (110a), a second build-up structure (110b), and protective layers (191, 196).

The circuit board (10) may include a core layer (100). The core layer (100) may be a member forming the foundation of the circuit board (10). With respect to the vertical direction, the core layer (100) may be disposed centrally within the circuit board (10). The material of the core layer (100) may include at least one element selected from the group consisting of glass, resin, plastic, and metal.

The core layer (100) may include a resin and glass fibers disposed within the resin as a reinforcing material. The glass fiber may be provided in plurality and may be disposed within the core layer (100) along the vertical direction. The glass fibers may have a longitudinal direction in the horizontal direction within the resin. However, this is not limiting, and the glass fibers may also be implemented as a single layer.

To suppress warpage of the circuit board (10), the vertical thickness of the core layer (100) may be greater than the vertical thickness of the first build-up structure (110a) or the vertical thickness of the second build-up structure (110b). However, the thickness of the core layer (100) may be freely provided without limitation, depending on the area of the circuit board (10) and the circuit design.

A first wiring portion (121) may be disposed on one surface of the core layer (100). The first wiring portion (121) may be disposed on the upper surface of the core layer (100) where the first build-up structure (110a) is disposed. The first wiring portion (121) may be electrically connected to a first pad portion (122) and a first via electrode (131) of the first build-up structure (110a).

A second wiring portion (123) may be disposed on the other surface of the core layer (100). A second wiring portion (123) may be disposed on the lower surface of the core layer (100) where the second build-up structure (110b) is disposed. The second wiring portion (123) may be electrically connected to a second pad portion (124) and a second via electrode (132) of the second build-up structure (110b).

The core layer (100) may include holes penetrating from the upper surface of the core layer (100) to the lower surface of the core layer (100). The hole may be provided in plurality and disposed along the horizontal direction of the core layer (100). A core via electrode (130) may be disposed within the holes.

The circuit board (10) may include a core via electrode (130). The core via electrode (130) may be disposed to penetrate at least a portion of the core layer (100). The core via electrode (130) may be disposed on the inner wall of the hole in the core layer (100) and may be disposed to overlap horizontally with the core layer (100). The first wiring portion (121) and the second wiring portion (123) may be electrically connected through the core via electrode (130). The core via electrode (130) may be provided in a plurality, and may be disposed along the horizontal direction of the core layer (100) in each of the plurality of holes.

A filling portion may be disposed within the core via electrode (130), and the core via electrode (130) may be disposed to surround the filling portion, disposed between the inner wall of the hole in the core layer (100) and the outer surface of the filling portion.

The first build-up structure (110a) may be disposed on one surface of the core layer (100). The first build-up structure (110a) may be disposed on the upper surface of the core layer (100). The second build-up structure (110b) may be disposed on the other surface of the core layer (100). The second build-up structure (110b) may be disposed on the lower surface of the core layer (100). The first build-up structure (110a) and the second build-up structure (110b) may be disposed vertically opposed to each other relative to the core layer (100). The first build-up structure (110a) and the second build-up structure (110b) may each include an insulating layer stacked vertically relative to the core layer (110). For ease of description in FIG. 1, the first build-up structure (110a) and the second build-up structure (110b) are each illustrated as single-layer structures via a first insulating layer (111) and a second insulating layer (112), respectively; however, this is not limiting. The first insulating layer (111) and the second insulating layer (112) may each be provided in plural numbers and disposed vertically on the upper and lower surfaces of the core layer (100), respectively.

The number of insulating layers in the first build-up structure (110a) may be the same as the number of insulating layers in the second build-up structure (110b). Accordingly, with respect to the core layer (100), warping of the circuit board (10) can be minimized. However, this is not limiting, and the number of insulating layers within the first build-up structure (110a) and the number of insulating layers within the second build-up structure (110b) may differ from one another.

The first build-up structure (110a) may include a first insulating layer (111), a first pad portion (122) disposed on the surface of the first insulating layer (210), and a first via electrode (131) disposed vertically to penetrate at least a portion of the first insulating layer (210).

The second build-up structure (110b) may include a second insulating layer (112), a second pad portion (124) disposed on the surface of the second insulating layer (112), and a second via electrode (132) disposed vertically and disposed to penetrate at least a portion of the second insulating layer (310).

As described above, the number of insulating layers constituting the first build-up structure (110a) shown in FIG. 1 and the number of insulating layers constituting the second build-up structure (110b) are exemplary. The circuit board (10) may comprise a greater number of insulating layers stacked vertically to form the first build-up structure (110a) and the second build-up structure (110b), respectively.

In this case, the first build-up structure (110a) may include wiring portions disposed on the surface of each of the plural first insulating layers (111), and via electrodes disposed vertically to electrically connect different wiring portions disposed to penetrate at least a portion of each of the plural first insulating layers (111). Similarly, the second build-up structure (110b) may include wiring portions disposed on the surface of each of a plurality of second insulating layers (112), and via electrodes disposed vertically to electrically connect different wiring portions disposed to penetrate at least a portion of each of the plurality of second insulating layers (112).

The first insulating layer (111) and the second insulating layer (112) may each be any insulating material, such as a photo-curable and/or thermosetting material. Thermosetting insulating materials may include insulating materials with inorganic and/or organic fillers dispersed within a resin, such as ABF (Ajinomoto Build-up Film) released by Ajinomoto Co., Inc., and prepregs (PPG) containing glass fibers within the resin. Furthermore, the aforementioned resins may exemplarily be epoxy resins, bis-maleimide triazine resins (BT resins), phenolic resins, etc., and the inorganic and/or organic fillers may be provided by materials such as silica and plastics. At least one of the first insulating layer (111) and the second insulating layer (112) may be a photo-curable insulator. Where it is a photo-curable insulator, at least one of the first insulating layer (111) and the second insulating layer (112) may be a PID (Photo Imageable Dielectric).

The circuit board (10) may include protective layers (191, 196). The protective layers (191, 196) may include a first protective layer (191) disposed on the surface of the first build-up structure (110a) and a second protective layer (196) disposed on the surface of the second build-up structure (110b). The first protective layer (191) and the second protective layer (196) can perform the function of preventing short circuits between solder when semiconductor devices are disposed on the surface of the circuit board (10) using materials such as solder, due to low wettability with the solder. They can also prevent the problem of external contaminants penetrating into the build-up structure and degrading reliability. The first protective layer (191) and the second protective layer (196) may each utilize a photo-curable insulating material. Therefore, the first protective layer (191) and the second protective layer (196) are provided as solder resist, not the aforementioned ABF, PPG, BT resin, or PID. However, this is not limited to this, and as described above, they may be provided with various materials capable of performing the function of preventing short circuits between solder due to low wettability with solder.

The first protective layer (191) may include a hole (192) to expose the pad portion (122) disposed on the surface of the first build-up structure (110a) upwards. The second protective layer (196) may include a hole (197) to expose the pad portion (124) disposed on the surface of the second build-up structure (110b) to the underside of the circuit board (10).

In the embodiment, the vertical stacking structure of multiple insulating layers through the core layer (110) within the circuit board (10) has been described by way of example, but this is not limiting, and the circuit board (10) may be a coreless structure where the core layer (110) is omitted. In this case, the circuit board (10) may comprise a plurality of vertically stacked insulating layers, and pad portions may be disposed on the surfaces of the plurality of insulating layers.

Hereinafter, the structure of the pad portion and via electrode within the circuit board (10) according to the embodiment shall be described. The structure of the pad portion and via electrode shall be described with reference to the first via electrode (131) and first pad portion (122) disposed on the first build-up structure (110a), and the arrangement structure of the pad portion and via electrode described below may also be applied by analogy to the second via electrode (132) and second pad portion (124) disposed on the second build-up structure (110b). Furthermore, for ease of description, the first insulating layer (111) shall be referred to as the insulating layer (111), the first via electrode (131) as the via electrode (131), and the first pad portion (122) as the pad portion (122).

Referring to FIGS. 1 and 2, the circuit board (10) may comprise an insulating layer (111), a via electrode (131) penetrating at least a portion of the insulating layer (111), and a pad portion (122) disposed on the insulating layer (111).

The via electrode (131) may be disposed to penetrate at least a portion of the insulating layer (111) and may electrically connect the pad portion (122) disposed on the insulating layer (111) to the wiring portion (121) disposed on the lower surface of the insulating layer (111). The via electrode (131) may have a shape wherein the horizontal width progressively decreases as it extends from the pad portion (122) towards the wiring portion (121). The insulating layer (111) includes a hole (119) for the placement of the via electrode (131), wherein the hole (119) may form a placement area for the via electrode (131). The hole (119) may be configured to penetrate the insulating layer (111) in a direction from the upper surface of the insulating layer (111), where the pad portion (122) is disposed, towards the wiring portion (121).

The via electrode (131) may include a plurality of regions disposed in a vertical direction. As illustrated in FIG. 2, the via electrode (131) may include a first layer (141), a second layer (142) disposed on the first layer (141), and a third layer (176) disposed between the first layer (141) and the second layer (142). With respect to the third layer (176), the first layer (141) and the second layer (142) may be vertically partitioned.

The first layer (141) and the second layer (142) may be regions plated by different seed layers.

As shown in FIG. 2, the circuit board (10) may comprise a first seed layer (160) and a second seed layer (170).

The first seed layer (160) may be implemented by electroless plating or a sputter method.

The first seed layer (160) may be disposed on at least a portion of the upper surface of the wiring portion (121) and at least a portion of the inner wall of the hole (119). The first layer (141) may be a region formed by plating through the first seed layer (160). The first seed layer (160) may include a first horizontal portion (162) and a first inner wall portion (164) protruding from the first horizontal portion (162). The first horizontal portion (162) may be disposed over the wiring portion (121). The first horizontal portion (162) may be disposed beneath the via electrode (131). The first horizontal portion (162) may be disposed beneath the first layer (141).

A first protrusion (163) may be disposed at each end of the first horizontal portion (162). The first protrusion (163) may have a shape protruding horizontally outward from the area of the first horizontal portion (162) overlapping perpendicularly with the hole (119). The first protrusion (163) may have a shape projecting horizontally outward from the lower end of the hole (119). The first protrusion (163) may be disposed to overlap perpendicularly with at least a portion of the first inner wall portion (164). When the surface of the wiring portion (121) that overlaps perpendicularly with the lower end of the via electrode (131) is designated as the first surface, and the surface that is offset perpendicularly from the lower end of the via electrode (131) is designated as the second surface, the first protrusion (163) may be disposed on the second surface.

During the formation process of the hole (119) for placing the via electrode (131), a protruding region extending horizontally may be formed at the lower end of the hole (119) facing the wiring portion (121). Accordingly, in the embodiment, the protruding region at the lower end of the aforementioned hole (119) can be sufficiently filled as a plating region via the first protrusion (163) extending horizontally from the lower end of the first inner wall portion (164).

The first inner wall portion (164) has a shape projecting upward from the surface of the first horizontal portion (162) and may be disposed on a portion of the inner wall of the hole (119). Plating through the first horizontal portion (162) and the first inner wall portion (164) may form the first layer (141). The upper end of the first inner wall portion (164) may be disposed in a stepped configuration downwardly relative to the upper end of the first layer (141), in the direction facing the wiring portion (121). The upper end of the first inner wall portion (164) may be vertically connected to the second seed layer (170) described below.

The size of the grains constituting the first seed layer (160) may be larger than the size of the grains constituting the first layer (141), the second layer (142), the wiring portion (121), and the pad portion (122).

The second seed layer (170) may be implemented by electroless plating or a sputter method.

The second seed layer (170) may be disposed on the surface of the insulating layer (111) between the first layer (141) and the second layer (142), on at least a portion of the inner wall of the hole (119), and where the pad portion (122) is disposed. The second layer (142) and the pad portion (122) may be regions formed by plating through the second seed layer (170).

A pattern portion (126) spaced horizontally from the pad portion (122) may be disposed on the surface of the insulating layer (111), and the pattern portion (126) may also be formed by plating through the second seed layer (170). Here, the pattern portion (126) may be another pad portion spaced horizontally from the pad portion (122), or a dummy pattern disposed on the circuit board (10).

The second seed layer (170) may include a third layer (176), a second inner wall portion (174) projecting from the third layer (176), and a second horizontal portion (172) disposed on the surface of the insulating layer (111).

The third layer (176) may be disposed between the first layer (141) and the second layer (142). The third layer (176) may be disposed on the upper surface of the first layer (141). The third layer (176) may be disposed on the lower surface of the second layer (142). The size of the grains constituting the third layer (176) may be larger than the size of the grains constituting the first layer (141) or the second layer (142).

A second protrusion (177), projecting towards the first inner wall portion (164) of the first seed layer (160), may be disposed at each horizontal end of the third layer (176), and the second protrusion (177) may be connected to the first inner wall portion (164). The second protrusion (177) may overlap at least partially with the first layer (141) in the horizontal direction. Consequently, no discontinuous region of the seed layer exists on the inner wall of the hole (119) for forming the via electrode (131), thereby improving the plating quality of the via electrode (131).

The second inner wall portion (174) has a shape projecting upwards from both ends of the third layer (176) and may be disposed on a portion of the inner wall of the hole (119). Here, the portion of the inner wall of the hole (119) where the second inner wall portion (174) is [symbol] arranged may be a different area from the portion of the inner wall of the hole (119) where the first inner wall portion (164) is arranged. The second inner wall portion (174) may be arranged to overlap horizontally with the second layer (142). The second layer (142) may be formed by plating through the third layer (176) and the second inner wall portion (174).

The second horizontal portion (172) may have a shape extending horizontally from the top of the second inner wall portion (174). The second horizontal portion (172) may be positioned on the insulating layer (111). The second horizontal portion (172) may have a horizontally separated region. The separated region of the second horizontal portion (172) may be a region removed by etching. At least a portion of the second horizontal portion (172) may be vertically overlapped with the pad portion (122). Plating through the second horizontal portion (172) may form the pad portion (122) and the aforementioned pattern portion (126).

The size of the grains constituting the second seed layer (170) may be larger than the size of the grains constituting the first layer (141), the second layer (142), the wiring portion (121), and the pad portion (122).

In conventional methods, plating of the pad portion and via electrode was achieved through a single seed layer. In this case, the seed layer is disposed on the upper surface of the wiring portion, the inner wall of the hole, and the surface of the insulating layer. For the realization of fine patterns, the thinner the seed layer thickness, the better; however, there is a problem where plating quality deteriorates due to differences in seed layer thickness across different regions on the upper surface of the wiring portion, the inner wall of the hole, and the surface of the insulating layer. Specifically, as the thickness of the seed layer placed on the wiring section at the bottom of the hole is formed thinner than that of the seed layer placed on the surface of the insulating layer, problems arise such as lifting phenomena on the pad surface due to differences in plating speed between areas, delamination between the bottom of the via electrode and the insulating layer, and voids within the via electrode.

According to the embodiment, by implementing the via electrode (131) via a plating method through multiple seed layers, the aforementioned deterioration in plating quality due to thickness variations across different regions of the seed layer can be prevented. Specifically, by forming the remaining portion of the via electrode (131) and the pad portion (122) via the plating method utilizing the third layer (176), the second inner wall portion (174), and the second horizontal portion (172), which are positioned closer to the surface of the insulating layer (111) compared to the conventional method, the thickness difference between the third layer (176) and the second horizontal portion (172) can be minimized, thereby minimizing lifting phenomena on the surface of the pad portion (122). Furthermore, in the case of sputtering, which is an anisotropic deposition method, discontinuities in the seed layer may occur due to delamination in the lower region of the hole (119). However, according to the embodiment, the formation structure of the via electrode (131) through multiple seed layers prevents a deterioration in plating quality due to seed layer discontinuities.

The vertical thickness (t1) of the first layer (141) may differ from the vertical thickness (t2) of the second layer (142). For example, the vertical thickness (t1) of the first layer (141) may be smaller than the vertical thickness (t2) of the second layer (142). In this case, the reduction in the vertical distance between the third layer (176) and the second horizontal section (172) may further reduce the thickness variation across different regions of the second seed layer (170).

As a modified embodiment, the vertical thickness (t1) of the first layer (141) may be equal to the vertical thickness (t2) of the second layer (142).

The thickness of the first seed layer (160) may be greater than the thickness of the second seed layer (170). Consequently, within the placement area of the pad portion (122), the relatively thin thickness of the second seed layer (170) facilitates the implementation of finer patterns.

Furthermore, during the formation process of the hole (119) for the placement of the via electrode (131), due to the protruding region at the bottom of the hole (119) facing the wiring portion (121), a crevice may occur at the bonding interface between the bottom of the via electrode (131) and the inner wall of the hole (119), and the bottom of the via electrode (131) and the inner wall of the hole (119). The aforementioned crevice arises during the formation of the circuit layer due to the difference in thermal expansion coefficients between the insulating layer and the circuit layer. As the crevice reduces the bonding strength between the insulating layer and the wiring portion, it poses a problem for the reliability of the circuit board. Therefore, by forming the first seed layer (160) relatively thick, the delamination area between the insulating layer and the circuit layer can be sufficiently filled by plating through the first seed layer (160). That is, according to the embodiment, by having a difference in seed layer thickness between areas requiring fine patterns and areas requiring high plating density, improvements in both fine patterns and plating quality can be achieved simultaneously.

Referring to FIGS. 3 to 6, the circuit board (10) according to the embodiment may have a first seed layer (160) formed within the insulating layer (111) in which the hole (119) is formed, as shown in FIG. 3. The first seed layer (160) may be disposed on the upper surface of the wiring portion (121), the inner wall of the hole (119), and the surface of the insulating layer (111), respectively. In this case, during the formation step of the first seed layer (160), a portion (168) of the first seed layer (160) may be disposed over the entire inner wall of the hole (119).

Next, as shown in FIG. 4, after attaching a mask (200) having a patterned hole (210) to the surface of the insulating layer (111), plating for forming the via electrode (131) may be performed. In this case, a first layer (141) of the via electrode (131) may be realized through the first horizontal portion (162) and a portion (168) of the first seed layer (160) disposed on the inner wall of the hole (119), and only a portion within the hole (119) may be filled by plating through the first layer (141).

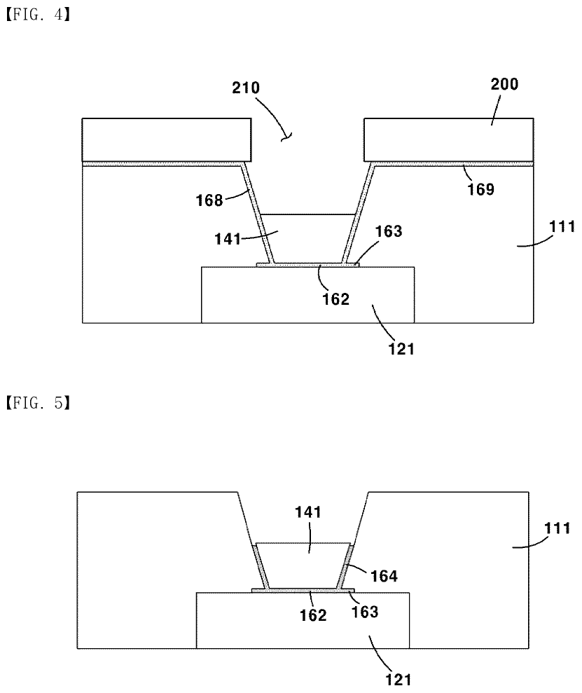

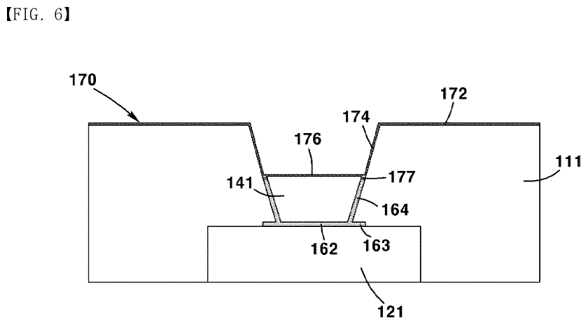

Next, as illustrated in FIG. 5, a portion of the first seed layer (160) may be removed by etching. Accordingly, as the region of the first seed layer (160) disposed on the surface of the insulating layer (111) and a portion (168) of the first seed layer (160) disposed on the inner wall of the hole (119) are removed, a first inner wall portion (164) may remain within the hole (119). As described above, the upper end of the first inner wall portion (164) may be staircasedly disposed lower than the upper surface of the first layer (141).

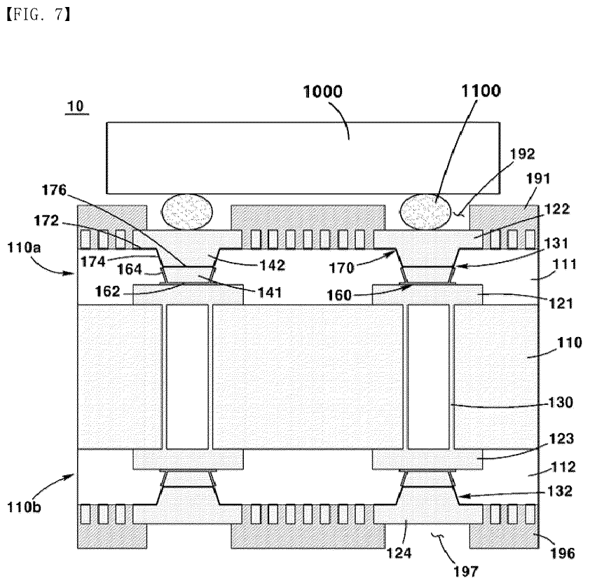

Next, as illustrated in FIG. 6, a second seed layer (170) may be formed for creating the second layer (142) and the pad portion (122). The second seed layer (170) may include a third layer (176) disposed on the first layer (141), a second inner wall portion (174) disposed on the inner wall of the hole (119), and a second horizontal portion (172) disposed on the surface of the insulating layer (111). Accordingly, after attaching a mask with a patterned hole on the insulating layer (111), second layer (142) of the via electrode (131) and pad portion (122) can be formed together on the third layer (176) by plating.

FIG. 7 is a cross-sectional view of a semiconductor package according to an embodiment of the present invention.

Referring to FIG. 7, the semiconductor package according to an embodiment of the present invention may include a semiconductor chip (1000) disposed on a circuit board (10). The semiconductor chip (1000) may be bonded to the pad portion (122) via a bonding portion (1100). For example, the bonding portion (1100) may be a solder ball that electrically and physically connects the pad portion (122) to a terminal of the semiconductor chip.

The foregoing description has illustrated that all components constituting an embodiment of the present invention may be combined or operate in combination. However, this does not necessarily limit the invention to such embodiments. That is to say, within the scope of the objectives of the present invention, all components may optionally be combined in one or more ways to operate. Furthermore, terms such as “include”, “comprise”, or “have” as described above, unless specifically stated otherwise, imply that the component may be present. Therefore, they should be interpreted as meaning that the component may include other components, not that it excludes other components. All terms, including technical or scientific terms, unless otherwise defined, have the same meaning as generally understood by a person skilled in the art to which the present invention pertains. Commonly used terms, such as those defined in dictionaries, should be interpreted in accordance with their meaning in the context of the relevant technology and, unless explicitly defined herein, should not be interpreted in an idealized or overly formalistic sense.

The foregoing description merely exemplifies the technical concept of the present invention. Those skilled in the art to which the present invention pertains will appreciate that various modifications and variations may be made without departing from the essential character of the invention. Therefore, the embodiments disclosed herein are intended to illustrate the technical concept of the present invention, not to limit it, and the scope of the technical concept of the present invention is not restricted by these embodiments. The scope of protection of the present invention shall be interpreted by the appended claims, and all technical concepts within the scope of these claims shall be interpreted as falling within the scope of the present invention.

Meanwhile, when a circuit board possessing the aforementioned features of the invention is utilized in IT devices such as smartphones, server computers, or televisions, or in home appliances, it can reliably perform functions such as signal transmission or power supply. For example, when a circuit board possessing the features of the present invention performs a semiconductor package function, it can safely protect the semiconductor chip from external moisture or contaminants, and can resolve issues such as leakage current, electrical short circuits between terminals, or electrical open circuits in the terminals supplying the semiconductor chip. Furthermore, when responsible for signal transmission functions, it can resolve noise issues. Consequently, the circuit board possessing the aforementioned features of the invention enables the stable functioning of IT devices or home appliances, thereby achieving functional integrity or technical interconnectivity between the entire product and the circuit board incorporating the present invention.

When a circuit board possessing the aforementioned features of the invention is utilized in a transport device such as a vehicle, it can resolve issues of signal distortion transmitted to the transport device, or safely protect the semiconductor chip controlling the transport device from external sources. Furthermore, it can address problems such as leakage current, electrical short circuits between terminals, or electrical open circuits in the terminals supplying the semiconductor chip, thereby further improving the stability of the transport device. Therefore, the transport device and the circuit board incorporating the present invention can achieve functional integration or technical interconnection.

1-15. (canceled)

16. A circuit board comprising:
an insulating layer; and
a via electrode penetrating at least a portion of the insulating layer,
wherein the via electrode includes a first layer, a second layer disposed on the first layer, and a third layer disposed between the first layer and the second layer and having a thickness thinner than thicknesses of the first layer and the second layer, and
wherein a grain size of the third layer is smaller than a grain size of the second layer.

17. The circuit board of claim 16, wherein the grain size of the third layer is smaller than a grain size of the first layer.

18. The circuit board of claim 16, further comprising a pad portion disposed on the insulating layer and connected with the via electrode in a vertical direction,
wherein the grain size of the pad portion is smaller than the grain size of the third layer.

19. The circuit board of claim 18, further comprising:
a hole which penetrates at least a portion of the insulating layer and in which the via electrode is disposed; and
a second seed layer including the third layer, a second inner wall portion extending upwards from the third layer and disposed on an inner wall of the hole and a second horizontal portion extended to a horizontal direction from an upper end of the second inner wall portion.

20. The circuit board of claim 19, wherein the second inner wall portion overlaps in a horizontal direction with the second layer.

21. The circuit board of claim 19, wherein the second horizontal portion overlaps the pad portion in a vertical direction.

22. The circuit board of claim 19, wherein a first seed layer includes a first horizontal portion disposed on a lower surface of the via electrode and a first inner wall portion extending upward from the first horizontal portion and disposed on the inner wall of the hole.

23. The circuit board of claim 22, wherein the first inner wall portion overlaps with the first layer in a horizontal direction.

24. The circuit board of claim 22, wherein the first inner wall portion is connected to the second inner wall portion to a vertical direction.

25. The circuit board of claim 22, further comprising a wiring portion disposed on a lower surface of the insulating layer,
wherein the first horizontal portion is disposed between the wiring portion and the via electrode.

26. The circuit board of claim 25, wherein the wiring portion includes a first surface vertically overlapped with a lower end of the via electrode and a second surface offset vertically from the lower end of the via electrode, and includes a protrusion extending from both ends of the first horizontal portion and disposed on the second surface.

27. The circuit board of claim 22, wherein the thickness of the first seed layer is greater than that of the second seed layer.

28. The circuit board of claim 25, wherein the upper end of the first inner wall portion is stepped downwards towards the wiring portion relative to an upper surface of the first layer.

29. The circuit board of claim 16, wherein a vertical thickness of the first layer is smaller than a vertical thickness of the second layer.

30. The circuit board of claim 26, wherein the protrusion overlaps perpendicularly with the first inner wall portion.

31. A semiconductor package comprising:
an insulating layer;
a semiconductor chip disposed on said insulating layer; and
a via electrode penetrating at least a portion of said insulating layer,
wherein the via electrode includes a first layer, a second layer disposed on said first layer, and a third layer disposed between the first layer and the second layer and having a thicknesses thinner than a thickness of both the first layer and the second layer, and
wherein a grain size of the third layer is smaller than a grain size of the second layer.

32. The semiconductor package of claim 31, wherein the grain size of the third layer is smaller than a grain size of the first layer.

33. The semiconductor package of claim 31, further comprising a pad portion disposed on the insulating layer and connected with the via electrode in a vertical direction, wherein the grain size of the pad portion is smaller than the grain size of the third layer.

34. The semiconductor package of claim 31, further comprising: a hole which penetrates at least a portion of the insulating layer and in which the via electrode is disposed; and a second seed layer including the third layer, a second inner wall portion extending upwards from the third layer and disposed on an inner wall of the hole and a second horizontal portion extended to a horizontal direction from an upper end of the second inner wall portion.

35. The semiconductor package of claim 34, wherein the second inner wall portion overlaps in a horizontal direction with the second layer.
